(19) United States
(12) Patent Application Publication
(10) Pub. No.: US 2019/0211259 A1
(43) Pub. Date: Jul. 11, 2019

(54) MIXTURE FOR OPTICAL DEVICES

(71) Applicant: MERCK PATENT GMBH, DARMSTADT (DE)

(72) Inventors: Sanaa KHALIL, Jerusalem (IL); Ehud SHAVIV, Modi'in (IL)

(73) Assignee: MERCK PATENT GMBH, DARMSTADT (DE)

(21) Appl. No.: 16/327,438

(22) PCT Filed: Aug. 18, 2017
(86) PCT No.: PCT/EP2017/070909

§ 371 Date: Feb. 22, 2019

(30) Foreign Application Priority Data
Aug. 22, 2016 (EP) 16185086.2

(51) Int. Cl. C09K 11/02; C09K 11/88; H01L 51/00

(52) U.S. Cl. CPC C09K 11/025; B82Y 20/00; H01L 51/0092; C09K 11/883

(57) ABSTRACT

The present invention relates to mixture comprising a semiconductor nanocrystal, optical medium, optical device and to fabrication thereof, the present invention further relates to use of mixture and to use of optical medium in an optical device.

### FIELD OF THE INVENTION

The present invention relates to mixture comprising a semiconductor nanocrystal, optical medium, optical device and to fabrication thereof, the present invention further relates to use of mixture and to use of optical medium in an optical device.

### BACKGROUND ART

Formulations comprising a semiconductor nanocrystal, and semiconductor nanocrystals are known in the prior art.

For example, as described in Igor Nabiev, et al., Analytical Biochemistry 324 (2004) 60-67; Jennifer A. Hollingsworth et al., Journal of American Chemical Society 2005, 127, 10126-10127; Moonsub Shim et al., The Journal of Physical Chemistry C 2015, 119, 20162-20168; The Journal of Physical Chemistry C 2009, 113, 12690-12698; US 2011/0014473 A1; U.S. Pat. No. 6,444,143 B2; WO 2013/078252 A1

### Patent Literature

1. US 2011/0014473 A1
2. U.S. Pat. No. 6,444,143 B2
3. WO 2013/078252 A1

### Non Patent Literature

4. Igor Nabiev, et al., Analytical Biochemistry 324 (2004) 60-67
5. Jennifer A. Hollingsworth et al., Journal of American Chemical Society 2005, 127, 10126-10127
6. Moonsub Shim et al., The Journal of Physical Chemistry C 2015, 119, 20162-20168
7. The Journal of Physical Chemistry C 2009, 113, 12690-12698

### SUMMARY OF THE INVENTION

However, the inventors newly have found that there is still one or more of considerable problems for which improvement is desired as listed below.
1. Novel mixture comprising a semiconductor nanocrystal, which can reduce or prevent quantum yield drop of the semiconductor nanocrystal of an optical medium upon thermal heating conditions, is desired.
2. Novel mixture comprising a semiconductor nanocrystal, which can lead long term stable emission of the semiconductor nanocrystal of an optical medium, is required.
3. Novel mixture comprising a semiconductor nanocrystal, which can be more easily used for fabrication of an optical medium comprising the semiconductor nanocrystal, is also desired.
4. Simple fabrication process for making an optical medium comprising a semiconductor nanocrystal, is requested.

The inventors aimed to solve one or more of the problems indicated above 1 to 4.

Surprisingly, the inventors have found a mixture comprising a semiconductor nanocrystal containing at least one IIB atom of the periodic table on the outermost surface of the semiconductor nanocrystal, a ligand represented by following formula (I), a transparent polymer attached onto the ligand, and a transparent matrix material

*—X—Y—Z (I)

wherein the formula, X is selected from the group consisting of —X^{a}—, —X^{a}—X^{b}—, —C(═X^{a})—X^{b}—, —NC(═X^{a})—X^{b}—, —X^{a}O₃—, —X^{a}—X^{b}O₃—, —PO₂H—, and PO₃H—, PO₄H—, with X^{a} and X^{b} being independently of each other S or Se, and X is attached onto the surface of the semiconductor nanocrystal; Y is selected from the group consisting of an alkylene chain having 1 to 25 carbon atoms, an alkoxylene chain having 1 to 25 carbon atoms, aryl group having 3 to 25 carbon atoms; Z is a polar group, anionic group or a cationic group, solves one or more of the above mentioned problems 1 to 4. Preferably, said mixture solves all the problems 1 to 4 at the same time.

In another aspect, the invention relates to an optical medium (100) comprising the mixture.

In another aspect, the invention further relates to use of the mixture in an optical medium fabrication process.

In another aspect, the invention also relates to use of the optical medium in an optical device.

In another aspect, the invention further relates to an optical device comprising the optical medium.

In another aspect, the invention furthermore relates to method for preparing of the mixture, wherein the method comprises the step (A):
(A) mixing the semiconductor nanocrystal containing at least one IIB atom of the periodic table on the surface of the semiconductor nanocrystal, a ligand represented by following formula (I), a transparent polymer attached on to the ligand, and the transparent matrix material

*—X—Y—Z (I)

wherein the formula, X is selected from the group consisting of —X^{a}—, —X^{a}—X^{b}, —C(═X^{a})—X^{b}—, —NC(═X^{a})—X^{b}—, —X^{a}O₃—, —X^{a}—X^{b}O₃—, —PO₂H—, and PO₃H—, PO₄H—, with X^{a} and X^{b} being independently of each other S or Se, and X is attached onto the surface of the semiconductor nanocrystal; Y is selected from the group consisting of an alkylene chain having 1 to 25 carbon atoms, an alkoxylene chain having 1 to 25 carbon atoms, aryl group having 3 to 25 carbon atoms; Z is a polar group, anionic group or a cationic group.

In another aspect, the invention relates to method for preparing of the optical medium (100), wherein the method comprises the step (x):

(x) providing the mixture onto a substrate.

Further advantages of the present invention will become evident from the following detailed description.

### DESCRIPTION OF DRAWINGS

FIG. 1: shows a cross sectional view of a schematic of one embodiment of an optical medium.

FIG. 2: shows the Normalized Quantum yield upon exposure to 80° C. in ambient conditions, as function of time for nanorods in PVA films fabricated in working example 1 and comparative example 1, 2.

FIG. 3: shows the Normalized Quantum yield measured as function of time for nanorods in PVA film with mercaptocarboxylic acids and PEI, which were exposed to 80° C. in inert conditions (Nitrogen).

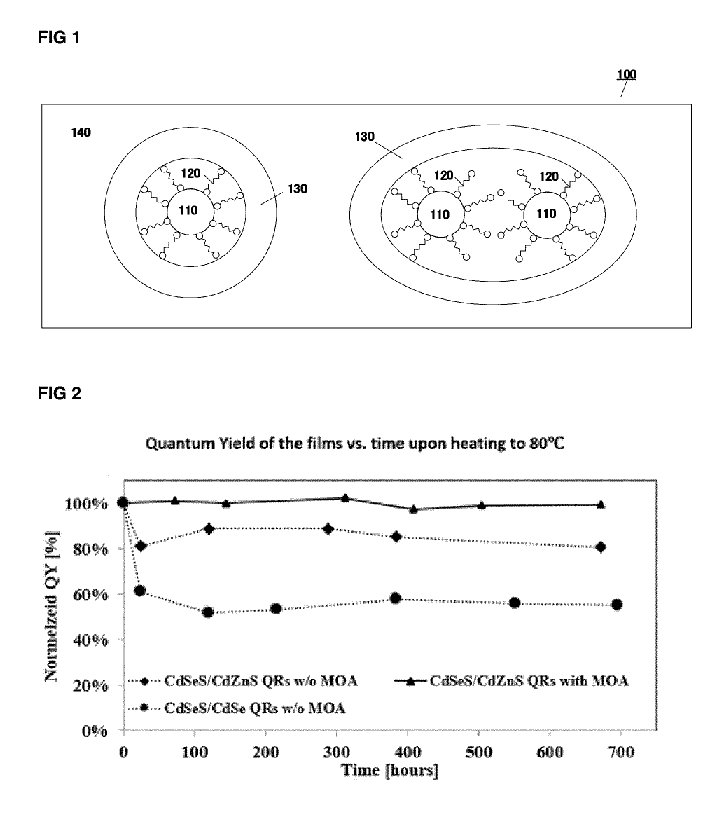

### LIST OF REFERENCE SIGNS IN FIG. 1

100. an optical medium
110. a semiconductor nanocrystal
120. a ligand
130. a transparent polymer
140. a transparent matrix material

### DETAILED DESCRIPTION OF THE INVENTION

In one aspect of the present invention, the novel mixture comprises a semiconductor nanocrystal containing at least one IIB atom of the periodic table on the outermost surface of the semiconductor nanocrystal, a ligand represented by following formula (I), a transparent polymer attached onto the ligand, and a transparent matrix material

*—X—Y—Z (I)

wherein the formula, X is selected from the group consisting of —X^{a}—, —X^{a}—X^{b}, —C(═X^{a})—X^{b}—, —NC(═X^{a})X^{b}—, —X^{a}O₃—, —X^{a}—X^{b}O₃—, —PO₂H—, and PO₃H—, PO₄H—, with X^{a} and X^{b} being independently of each other S or Se, and X is attached onto the surface of the semiconductor nanocrystal; Y is selected from the group consisting of an alkylene chain having 1 to 25 carbon atoms, an alkoxylene chain having 1 to 25 carbon atoms, aryl group having 3 to 25 carbon atoms; Z is a polar group, anionic group or a cationic group, solves one or more of the above mentioned problems 1 to 4.

Preferably the mixture solves all the problems 1 to 4 at the same time.

### —Semiconductor Nanocrystal

According to the present invention, as a semiconductor nanocrystal, a wide variety of publically known light luminescent semiconductor nanocrystals containing at least one IIB atom of the periodic table on the outermost surface of the semiconductor nanocrystal can be used as desired.

A type of shape of the semiconductor nanocrystal of the present invention is not particularly limited.

Any type of semiconductor nanocrystals, for examples, spherical shaped, elongated shaped, star shaped, polyhedron shaped semiconductor nanocrystals, can be used in this way.

In a preferred embodiment of the present invention, the semiconductor nanocrystals comprise a core/shell structure, in which at least the outermost shell comprises one IIB atom of the periodic table.

According to the present invention, preferably, the shall of the semiconductor nanocrystal is a single shell layer, double shell layers, or multishell layers having more than two shell layers.

More preferably, the semiconductor nanocrystal of the present invention is a quantum sized material, with furthermore preferably being of a quantum dot material, or a quantum rod material.

In a preferred embodiment of the present invention, the IIB atom is Zn, or Cd, with more preferably being of Zn.

Without wishing to be bound by theory, it is believed that Zn atom is more suitable from the view point of less toxicity and/or better compatibility to the ligand of the present invention.

According to the present invention, the term “nano” means the size in between 1 nm and 999 nm.

Thus, according to the present invention, semiconductor nanocrystal is taken to mean that a fluorescent semiconductor material which size of the overall diameter is in the range from 1 nm to 999 nm. And in case of the semiconductor nanocrystal has non spherical shape, such as an elongated shape, the length of the overall structures of the semiconductor nanocrystal is in the range from 1 nm to 999 nm.

According to the present invention, the term “quantum sized” means the size of the inorganic semiconductor material itself without ligands or another surface modification, which can show the quantum size effect.

In a preferred embodiment of the present invention, the semiconductor nanocrystal is selected from the group consisting of II-VI, III-V, IV-VI, tertiary or quaternary semiconductors and combinations of any of these.

In case of the semiconductor nanocrystal does not have any core/shell structure, the semiconductor nanocrystal comprises IIB atom of the periodic table and material of the semiconductor nanocrystal can preferably be selected from the group consisting of CdS, CdSe, CdTe, ZnS, ZnSe, ZnSeS, ZnTe, ZnO, InPZnS, InPZn, Cu₂(ZnSn)S₄.

In a preferred embodiment of the present invention, the semiconductor nanocrystals comprise a core/shell structure, in which at least the outer most shell comprises one IIB atom of the periodic table.

More preferably, a core of the semiconductor nanocrystal is selected from the group consisting of Cds, CdSe, CdTe, ZnS, ZnSe, ZnSeS, ZnTe, ZnO, GaAs, GaP, GaAs, GaSb, HgS, HgSe, HgSe, HgTe, InAs, InP, InPZnS, InPZn, InSb, AlAs, AlP, AlSb, Cu₂S, Cu₂Se, CuInS₂, CuInSe₂, Cu₂(ZnSn)S₄, Cu₂(InGa)S₄, TiO₂ alloys and combination of any of these.

In a preferred embodiment of the present invention, shell is selected from the group consisting of II-VI, III-V, or IV-VI, tertiary or quaternary semiconductors with the condition that the outermost shell comprises IIB atom.

For example, for red emission use CdSe/CdS, CdSeS/CdZnS, CdSeS/CdS/ZnS, ZnSe/CdS, CdSe/ZnS, InP/ZnS, InP/ZnSe, InP/ZnSe/ZnS, InPZn/ZnS, InPZn/ZnSe/ZnS dots or rods, ZnSe/CdS, ZnSe/ZnS or combination of any of these, can be used preferably.

For example, for green emission use CdSe/CdS, CdSeS/CdZnS, CdSeS/CdS/ZnS, ZnSe/CdS, CdSe/ZnS, InP/ZnS, InP/ZnSe, InP/ZnSe/ZnS, InPZn/ZnS, InPZn/ZnSe/ZnS, ZnSe/CdS, ZnSe/ZnS or combination of any of these, can be used preferably.

Generally, quantum sized materials such as quantum dot materials, and/or quantum rod materials can emit tunable, sharp and vivid colored light due to “quantum confinement” effect.

As a quantum dot, publically available quantum dots containing at least one IIB atom of the periodic table on the outermost surface of the semiconductor nanocrystal, for examples, CdSeS/ZnS alloyed quantum dots product number 753793, 753777, 753785, 753807, 753750, 753742, 753769, 753866, InP/ZnS quantum dots product number 776769, 776750, 776793, 776777, 776785, or CdSe/ZnS alloyed quantum dots product number 754226, 748021, 694592, 694657, 694649, 694630, 694622 from Sigma-Aldrich, can be used preferably as desired.

In some embodiments, the semiconductor nanocrystal can be selected from a anisotropic shaped structure, for example quantum rod material to realize better out-coupling effect (for example ACS Nano, 2016, 10 (6), pp 5769-5781) Examples of quantum rod material have been described in, for example, the international patent application laid-open No. WO2010/095140A.

In a preferred embodiment of the invention, the length of the overall structures of the quantum rods is from 8 nm to 200 nm. More preferably, from 15 nm to 100 nm. The overall diameter of the said quantum rod material is in the range from 1 nm to 20 nm. More preferably, it is from 3 nm to 10 nm.

### —Ligand

According to the present invention, any types of publically known ligands represented by following formula (I)

*—X—Y—Z (I)

wherein the formula, X is selected from the group consisting of —X^{a}—, —X^{a}—X^{b}, —C(═X^{a})—X^{b}—, —NC(═X^{a})—X^{b}—, —X^{a}O₃—, —X^{a}—X^{b}O₃—, —PO₂H—, and PO₃H—, PO₄H—, with X^{a} and X^{b} being independently of each other S or Se, and X is attached onto the surface of the semiconductor nanocrystal; Y is selected from the group consisting of an alkylene chain having 1 to 25 carbon atoms, an alkoxylene chain having 1 to 25 carbon atoms, aryl group having 3 to 25 carbon atoms; Z is a polar group, anionic group or a cationic group, can be used preferably.

According to the present invention, the alkyl chain, or the alkoxy chain in formula (I) can be a straight or branched. In some embodiment, an alkyl chain having 1 to 25 carbon atoms or an alkoxy chain having 1 to 25 carbon atoms can be unsubstituted, mono- or polysubstituted by halogen or CN, it being also possible for one or more non-adjacent CH₂ groups to be replaced, in each occurrence independently from one another, by —O—, —S—, —NH—, —N(CH₃)—, —CO—, —COO—, —OCO—, —O—CO—O—, —S—CO—, —CO—S—, —CH═CH—, —CH═CF—, —CF═CF— or —C≡C— in such a manner that oxygen atoms are not linked directly to one another.

In a preferred embodiment of the present invention, said alkyl chain is an alkyl chain having 1 to 15 carbon atoms, said alkoxy chain is an alkoxy chain having 1 to 15 carbon atoms, and said aryl group is an aryl group having 3 to 15 carbon atoms.

In a preferred embodiment of the present invention, said alkyl chain or said alkoxy chain is a straight chain.

In a preferred embodiment of the present invention, X of formula (I) is selected from the group consisting of —S—, —S—S—, —C(═S)—S—, —N—C(═S)—S—, SO₃—, —S—SO₃—, —PO₂H—, and PO₃H—, with more preferably being of S atom.

Without wishing to be bound by theory, it is believed that the X of formula (I), especially S atom (preferably in thiolate form), leads better bonding to a IIB atom of a semiconductor nanocrystal, Especially it is believed, without wishing to bound by theory, that S atom as the X of formula (I) leads much better bonding to a Zn atom of a semiconductor nanocrystal.

In a preferred embodiment of the present invention, the Z of the formula (I) is selected from the group consisting of —COOR, —NR₂, —COR, —CONH₂, —OH; SO₃⁻, SO₄⁻, PO₃⁻, NR₄⁺ and PN₄⁺, wherein R is hydrogen atom, or alkyl chain having 1 to 25 carbon atoms with more preferably being of hydrogen atom or alkyl chain having 1 to 15 carbon atoms.

Without wishing to be bound by theory, it is believed that the Z of the formula (I) may lead better chemical interaction (via hydrogen bonding or electrostatic interaction) between the ligand and a transparent polymer attached onto the ligand.

In a more preferred embodiment of the present invention, the ligand is selected from mercaptocarboxylic acids. Such as mercapto-octanoic acid (MOA), mercaptohexanoic acid (hereafter MHA). More preferably, it is omega-mercapto-carboxylic acids. These mercaptocarboxylic acids can be used singly or it can be mixed.

In some embodiments of the present invention, optionally, the semiconductor nanocrystal such as quantum rod and/or quantum dot may comprise a different type of surface ligand in addition to the ligand represented by the formula (I).

Thus, in some embodiments of the present invention, the outer surface of the semiconductor nanocrystal can be over coated with a different type of surface ligand together with the ligand represented by the formula (I), if desired.

Without wishing to be bound by theory it is believed that such a surface ligands may lead to disperse the nanosized fluorescent material in a solvent more easily.

### —Transparent Polymer

According to the present invention, a wide variety of publically known transparent polymers suitable for optical mediums such as optical devices can be used in this way.

According to the present invention, the term “transparent” means at least around 60% of incident light transmit at the thickness used in an optical medium and at a wavelength or a range of wavelength used during operation of an optical medium. Preferably, it is over 70%, more preferably, over 75%, the most preferably, it is over 80%.

According to the present invention the term “polymer” means a material having a repeating unit and having the weight average molecular weight (Mw) 1000 or more.

In a preferred embodiment of the present invention, the weight average molecular weight (Mw) of the transparent polymer (130) is in the range from 1,000 to 150,000.

More preferably it is from 5,000 to 80,000 with more preferably being from 10,000 to 40,000.

The weight average molecular weight (Mw) of the transparent polymer (130) can be measured with Static Light Scattering Spectrophotometer “Zetasizer Nano ZS” (Malvern).

In a preferred embodiment of the present invention, the transparent polymer contains a group selected from the group consisting of phosphate, phosphine, phosphine oxide, phosphonate, thiol, amino, carboxylate, carboxylic ester, hetero cycle, silane, sulfonate, hydroxyl and a combination of any of these, with more preferably being of amino, phosphate, carboxylate, or a combination of any of these.

For examples, polyvinyl pyridine, polyvinyl phosphonic acid, polystyrene sulfonate, polystyrene phosphonate, polystyrene phosphonate acid, polyethylenimine.

In a preferred embodiment of the present invention, the transparent polymer is a branched polymer.

According to the present invention, the term “branched polymer” means a polymer having at least one branching point where a second chain of monomers branched off from the first chain.

In a preferred embodiment of the present invention, the branched polymer is selected from the group consisting of a dendrimer, dendronized polymer, hyperbranched polymer, and a polymer brush, and a star polymer, and a combination of any of these.

According to the present invention, the term “dendronized polymer” means a polymer having a linear polymer chain in which dendrons are regularly branched onto the linear polymer chain.

According to the present invention, the term “Dendron” taken to mean that a polymer repetitively branched but not symmetrically branched around the core.

The term “Dendrimer” means a polymer having a core and symmetrically and repetitively branched around the core.

According to the present invention, the term “hyperbranched polymer” taken to mean that a polymer having one or more of 1^{st} branching points on the first chains and at least one of second chains of monomers branched off from the first chains also has at least one or more of 2^{nd} branching points, here the term “hyperbranched polymer” does not include “dendronized polymers” and “Dendrimers”.

The hyperbranched polymers, according to the invention, can be characterized by a degree of branching (DB) which represents the percentage of dendritic and terminal monomers among the total monomers in the polymer and represented by the following formula (1);

DB=D+T/(D+T+L)*100%— formula(1)

(wherein the formula, the symbol “D” means the number of branching points in a polymer, the symbol “T” is the number of terminal parts in a polymer, and the symbol “L” is number of the unbranched parts in a polymer. Like described in Mitsuru Ueda, Landfall vol. 77, 2013, pp 16-21)

More preferably, the branched polymer is a dendrimer, dendronized polymer, hyperbranched polymer or a combination of any of these.

In a preferred embodiment of the present invention, the transparent polymer is a branched polymer selected from the group consisting of a dendrimer, dendronized polymer, hyperbranched polymer or a combination of any of these, wherein the transparent polymer comprising a group selected from the group consisting of phosphate, phosphine, phosphine oxide, phosphonate, thiol, amino, carboxylate, carboxylic ester, hetero cycle, silane, sulfonate, hydroxyl and a combination of any of these, with more preferably being of amino, phosphate, carboxylate, or a combination of any of these, and wherein the weight average molecular weight (Mw) of the transparent polymer is in the range from 1,000 to 150,000, with being more preferably in the range from 5,000 to 80,000. Even more preferably it is from 10,000 to 40,000.

For examples, polyethylenimine (hereafter “PEI”) can be used preferably. Other types of branched polymers could be poly(sulfone amine), poly(ester amine), poly(amide amines), poly(urea urethane), poly(amine ester), poly(ester amides), polyester or block copolymers combining these polymers.

### —Transparent Matrix Material

According to the present invention, a wide variety of publically known transparent matrix materials suitable for optical devices can be used in this way.

In some embodiments of the present invention, the transparent matrix material can be selected from one or more of the members of the group consisting of an alkoxide represented by following formula (II), an organic polymer, and a polysiloxane.

Mz(OR)zx (II)

wherein the formula (II), M is Si, Al, Va or Ti; R is an alkyl chain having 1 to 25 carbon atoms; 1≤z; x is an oxidation number of M. Preferably, z is an integer 1 or more.

In a preferred embodiment of the present invention, the alkyl chain of the formula (II) is an alkyl chain having 1 to 15 carbon atoms.

In some embodiments of the present invention, the transparent matrix material can be an organic polymer or a polysiloxane.

In some embodiments of the present invention, the glass transition temperature (Tg) of the organic polymer is 70° C. or more and 250° C. or less.

Tg can be measured based on changes in the heat capacity observed in Differential scanning colorimetry like described in

http://pslc.ws/macrog/dsc.htm.

In a preferred embodiments of the present invention, the transparent matrix material contains a group selected from the group consisting of —OH, —CN, —F, and —Cl.

In a preferred embodiments of the present invention, the transparent matrix material is an organic polymer containing a group selected from the group consisting of —OH, —CN, —F, and —Cl

For examples, as the organic polymer for the transparent matrix material, polyvinyl alcohols, polyacrylonitrile, polyvinylidene chloride, ethylene vinylalcohol like disclosed in the polymer handbook 4^{th} edition (J. Brandrup, et al.,) can be used preferably.

More preferably, polyvinyl alcohols is used as the organic polymer for the transparent matrix material.

For examples of polysiloxanes for the transparent matrix material, polysiloxanes like disclosed in WO 2013/151166 A1, U.S. Pat. No. 8,871,425 B2 can be used preferably.

Thus, according to the present invention, in some embodiments, the transparent matrix material can be one or more of the members of the group consisting of polyvinyl alcohol, polyvinylidene chloride, polyacrylonitrile, polyvinylidene fluoride, and ethyl vinyl alcohol.

In a preferred embodiment of the present invention, the weight average molecular weight (Mw) of the polymer as the transparent matrix material is in the range from 1,000 to 300,000.

More preferably it is from 20,000 to 250,000 with more preferably being from 40,000 to, 200,000.

### —Solvent

In some embodiments of the present invention, the mixture can further comprise solvent, if necessary.

Type of solvent is not particularly limited.

In some embodiments of the present invention, the solvent can be selected from the group consisting of purified water; ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, and glycerin; esters, such as, ethyl 3-ethoxypropionate, methyl 3-methoxypropionate and ethyl lactate; and cyclic asters, such as, γ-butyro-lactone; chlorinated hydrocarbons, such as chloroform, dichloromethane, chlorobenzene, dichlorobenzene.

Those solvents are used singly or in combination of two or more, and the amount thereof depends on the coating method and the thickness of the coating.

More preferably, propylene glycol alkyl ether acetates, such as, propylene glycol monomethyl ether acetate (hereafter “PGMEA”), propylene glycol monoethyl ether acetate, propylene glycol monopropyl ether acetate, purified water or alcohols can be used.

Even more preferably, purified water can be used.

The amount of the solvent in the photosensitive composition can be freely controlled according to the method of coating the composition. For example, if the composition is to be spray-coated, it can contain the solvent in an amount of 90 wt. % or more. Further, if a slit-coating method, which is often adopted in coating a large substrate, is to be carried out, the content of the solvent is normally 60 wt. % or more, preferably 70 wt. % or more.

In another aspect, the present invention also related to use of the mixture in an optical medium fabrication process.

—Optical Medium

In another aspect, the present invention further relates to an optical medium (100) comprising the mixture.

Regarding the transparent matrix material, the semiconductor nanocrystal (110), the ligand (120), transparent polymer (130) and the transparent matrix material (140), are described in the section “Semiconductor nanocrystal”, “Ligand”, “Transparent polymer”, and in the section named “Transparent matrix material”.

In some embodiments of the present invention, the optical medium can be an optical film, for example, a color filter, color conversion film, remote phosphor tape, or another film or filter In another aspect, the present invention also relates to use of the optical medium in an optical device.

### —Optical Device

In another aspect, the invention further relates to an optical device comprising the optical medium.

In some embodiments of the present invention, the optical device can be a liquid crystal display, Organic Light Emitting Diode (OLED), backlight unit for display, Light Emitting Diode (LED), Micro Electro Mechanical Systems (here in after “MEMS”), electro wetting display, or an electrophoretic display, a lighting device, and/or a solar cell.

### —Fabrication Process

In another aspect, the present invention furthermore relates to method for preparing of the mixture, wherein the method comprises the step (A):

(A) mixing the semiconductor nanocrystal containing at least one IIB atom of the periodic table on the surface of the semiconductor nanocrystal, a ligand represented by following formula (I), a transparent polymer attached onto the ligand, and the transparent matrix material.

*—X—Y—Z (I)

wherein the formula, X is selected from the group consisting of —X^{a}—, —X^{a}—X^{b}—, —C(═X^{a})—X^{b}—, —NC(═X^{a})—X^{b}—, —X^{a}O₃—, —X^{a}—X^{b}O₃—, —PO₂H—, and PO₃H—, PO₄H—, with X^{a} and X^{b} being independently of each other S or Se, and X is attached onto the surface of the semiconductor nanocrystal (110); Y is selected from the group consisting of an alkylene chain having 1 to 25 carbon atoms, an alkoxylene chain having 1 to 25 carbon atoms, aryl group having 3 to 25 carbon atoms; Z is a polar group, anionic group or a cationic group.

Preferably, the mixing condition in step (A) is carried out at room temperature.

Preferably, the mixing condition in step (A) is carried out at room temperature under inert condition such as under N₂ condition.

In a preferred embodiment of the present invention, in step (A), solvent is also additionally added. Preferably, the solvent is selected from the group consisting of purified water; ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; aromatic hydrocarbons, such as, benzene, toluene and xylene; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, and glycerin; esters, such as, ethyl 3-ethoxypropionate, methyl 3-methoxypropionate and ethyl lactate; and cyclic asters, such as, γ-butyro-lactone; chlorinated hydrocarbons, such as chloroform, dichloromethane, chlorobenzene, dichlorobenzene.

Those solvents are used singly or in combination of two or more, and the amount thereof depends on the coating method and the thickness of the coating.

More preferably, propylene glycol alkyl ether acetates, such as, propylene glycol monomethyl ether acetate (hereafter “PGMEA”), propylene glycol monoethyl ether acetate, propylene glycol monopropyl ether acetate, purified water or alcohols can be used.

Even more preferably, purified water can be used.

In step (A), as a precursor of the transparent matrix material, for example, tetraethyl orthosilicate (TEOS), methyl triethoxysilane (MTEOS), sodium silicate, lithium silicate, kalium silicate, aluminum isopropoxide, Tripropyl orthoaluminate Al (OC3H7)3 (TPOAI), Titanium alkoxide, vanadium alkoxide or a combination of any of these can be used preferably.

Or polymers as the matrix material described in—Transparent matrix material—can be used preferably as desired.

For examples, like described in Ji-Guang Li, et. al., Chem. Mater. 2008, 20, 2274-2281, Weihua Di, et. al., Journal of Materials Chemistry, 2012, 22, 20641, and/or Yoshio Kobayashi, et. al., J Sol-Gel Sci Technol, 2010, 55; 79-85.

In another aspect, the present invention also relates to method for preparing of the optical medium (100), wherein the method comprises the step (x):

(x) providing the mixture onto a substrate.

According to the present invention, to provide the mixture onto a substrate, any type of publically known coating method can be used preferably. Such as ink jet printing, nozzle printing, immersion coating, gravure coating, roll coating, bar coating, brush coating, spray coating, doctor blade coating, flow coating, spin coating, and slit coating.

Preferably, step (x) is carried out under inert condition such as under N₂ condition.

### Effect of the Invention

According to the present invention, the invention provides,
1. a novel mixture comprising a semiconductor nanocrystal, which can reduce or prevent quantum yield drop of the semiconductor nanocrystal of an optical medium upon thermal heating conditions,
2. a novel mixture comprising a semiconductor nanocrystal, which can lead long term stable emission of the semiconductor nanocrystal of an optical medium,
3. a novel mixture comprising a semiconductor nanocrystal, which can be more easily used for fabrication of an optical medium comprising the semiconductor nanocrystal,
4. a simple fabrication process for making an optical medium comprising a semiconductor nanocrystal.

### Definition of Terms

The term “semiconductor” means a material which has electrical conductivity to a degree between that of a conductor (such as copper) and that of an insulator (such as glass) at room temperature.

The term “inorganic” means any material not containing carbon atoms or any compound that containing carbon atoms ionically bound to other atoms such as carbon monoxide, carbon dioxide, carbonates, cyanides, cyanates, carbides, and thiocyanates.

The term “emission” means the emission of electromagnetic waves by electron transitions in atoms and molecules.

The working examples 1-3 below provide descriptions of the present invention, as well as an in detail description of their fabrication.

### Working Examples

### Working Example 1

### 1-1: Preparation of Mixture Comprising Semiconductor Nanocrystals

5 g of CdSeS/CdZnS quantum rods (semiconductor nanocrystals) was dissolved in 10 mL of toluene, and precipitated by addition of 5 mL of MeOH, then it was centrifuged for 7 minutes at 4000 rpm. That procedure was repeated once again.

After the second precipitation, the supernatant was decanted and the solid was dried under Argon flow at room temperature. The cleaned quantum rods were dissolved in 3 mL of Chloroform. Instead of Chloroform, Dichloromethane can be used to dissolve the cleaned semiconductor nanocrystals.

On a separate vial, mercaptocarboxylic acid (hereafter MCA) (from Sigma Aldrich) was dissolved in MeOH and activated by addition of NH₄OH. (weight ratio of cleaned semiconductor nanocrystals:MCA was 1:2, and volume ratio of MCA:MeOH:NH₄OH was 1:2:2.), then the obtained MCA solution was added dropwise to the semiconductor nanocrystal solution. The solution became turbid and a phase separation was obtained.

In this working example, as MCA, 8-mercapto-octanoic acid (MOA) was used.

Then the obtained biphasic solution was mixed well by vigorous stirring and allowed to stand for several minutes to equilibrate.

After that, a green clear solution was formed above the colorless Chloroform (CHCl₃) phase which indicates a complete transfer of the semiconductor nanocrystals to aqueous phase. The aqueous layer was collected carefully. And then, 4 mL of polyethyleneimine (hereafter PEI) (from Sigma Aldrich) in water was added (0.125 g/mL for 100 mg of the cleaned semiconductor nanocrystals.)

The solution was stirred for 3 hours to ensure good attachment of PEI onto the carboxylate group of MOA.

In the obtained solution, the concentration of semiconductor nanocrystals in water was approximately 3 wt. %.

120 μl of polymethylmethacrylate microspheres (cross link beads with 6 um of average diameter supplied by Microbeads) dispersed in aqueous solution and 100 μl of the obtained solution comprising the semiconductor nanocrystals from the previous steps were mixed together.

Here, polymethylemethacrylate microspheres are not mandatory.

You can create the mixture without polymethylemethacrylate microspheres.

Then, the obtained mixture was added to 4 g of aqueous solution of 6 wt. % of polyvinyl alcohol (hereafter PVA) (Mw is 146,000-186,000 g/mole, 99+% hydrolyzed; from Sigma Aldrich).

Finally, mixture comprising a semiconductor nanocrystal was obtained.

### 1-2: Fabrication of Optical Medium

The finally obtained mixture from 1-1 was poured onto a mold or coated onto a Polyethylene terephthalate (hereafter PET) surface, followed by 12 hours of drying at 380° C. under ambient condition.

Finally, optical film 1 was obtained.

### Working Example 2

A mixture comprising semiconductor nanocrystals and optical film were prepared in the same manner as described in the working example 1 except for 6-mercaptohexanoic acid (here after MHA) was used instead of MOA.

### Comparative Example 1

A mixture comprising semiconductor nanocrystals and optical film were prepared in the same manner as described in the working example 1 except for MOA was not used.

### Comparative Example 2

A mixture comprising semiconductor nanocrystals and optical film were prepared in the same manner as described in the comparative example 1 except for CdSe/CdS nanocrystals were used instead of CdSe/CdZnS nanocrystals.

### Working Example 3: Thermal Stability Measurement

The films from working example 1 and comparative example 1, 2 were heated in an oven at 80° C., 2% of relative humidity (hereafter RH) in air.

The absolute Quantum Yield (QY) values were measured directly by using an absolute photoluminescence QY spectrometer (Hamamatsu model: Quantaurus C11347)

FIG. 2 shows the Normalized Quantum yield as function of time for nanorods of the films from working example 1, and comparative working example 1, 2.

The film with combination of MOA and PEI show improved thermal stability.

Separately, the films from working example 1 and 2 were placed on a heating plate inside a glove-box under inert condition (N₂). And the films were heated.

QY values of each films were measured in the same manner.

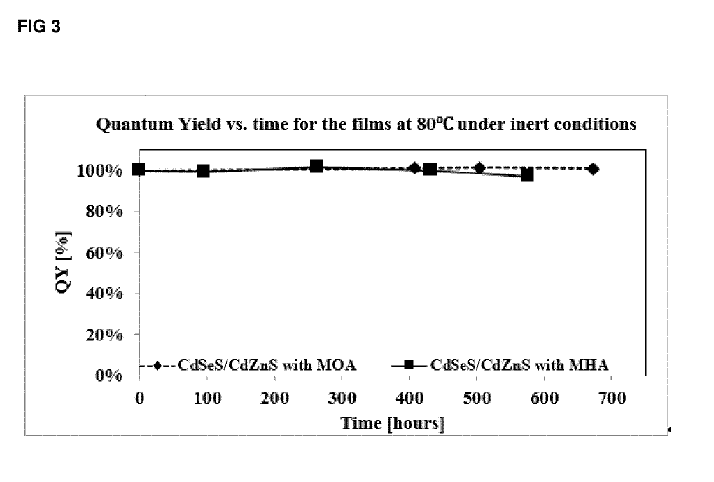

FIG. 3 shows shows the Normalized Quantum yield as function of time for nanorods film with mercaptocarboxylic acids and PEI which exhibit high thermal stability upon heating to 80° C. under inert atmosphere (N₂).

1. A mixture comprising a semiconductor nanocrystal (110) containing at least one IIB atom of the periodic table on the outermost surface of the semiconductor nanocrystal, a ligand (120) represented by following formula (I), a transparent polymer (130) attached onto the ligand, and a transparent matrix material (140)
*—X—Y—Z (I)
wherein the formula, X is selected from the group consisting of —X^{a}—, —X^{a}—X^{b}—, —C(═X^{a})—X^{b}—, —NC(═X^{a})—X^{b}—, —X^{a}O₃—, —X^{a}—X^{b}O₃—, —PO₂H—, and PO₃H—, PO₄H—, with X^{a} and X^{b} being independently of each other S or Se, and X is attached onto the surface of the semiconductor nanocrystal; Y is selected from the group consisting of an alkylene chain having 1 to 25 carbon atoms, an alkoxylene chain having 1 to 25 carbon atoms, aryl group having 3 to 25 carbon atoms; Z is a polar group, anionic group or a cationic group.

2. The mixture according to claim 1, wherein the transparent matrix material (140) is selected from one or more members of the group consisting of an alkoxide represented by following formula (II), an organic polymer, and a polysiloxane
Mz(OR)zx (II)
wherein the formula (II), M is Si, Al, Va or Ti; R is an alkyl chain having 1 to 25 carbon atoms; 1≤z; x is an oxidation number of M. Preferably, z is an integer 1 or more.

3. The mixture according to claim 1, wherein the transparent matrix material (140) is an organic polymer or a polysiloxane.

4. The mixture according to claim 1, wherein the transparent matrix material (140) contains a group selected from the group consisting of —OH, —CN, —F, and —Cl.

5. The mixture according to claim 1, wherein the glass transition temperature (Tg) of the organic polymer is 70° C. or more.

6. The mixture according to claim 1, wherein the transparent matrix material (140) is polyvinyl alcohol, polyvinylidene chloride, polyacrylonitrile, polyvinylidene fluoride, ethyl vinyl alcohol or a combination of any of these.

7. The mixture according to claim 1, wherein X of formula (I) is selected from the group consisting of —S—, —S—S—, —C(═S)—S—, —NC(═S)—S—, SO₃—, —S—SO₃—, —PO₂H—, and PO₃H—.

8. The mixture according to claim 1, wherein X of formula (I) is S.

9. The mixture according to claim 1, wherein the Z of the formula (I) is selected from the group consisting of —COOR, —NR₂, —COR, —CONH₂, —OH; SO₃⁻, SO₄⁻, PO₃⁻, NR₄⁺ and PN₄⁺, wherein R is hydrogen atom, or alkyl chain having 1 to 25 carbon atoms.

10. The mixture according to claim 1, wherein the transparent polymer (130) contains a group selected from the group consisting of phosphate, phosphine, phosphine oxide, phosphonate, thiol, amino, carboxylate, carboxylic ester, hetero cycle, silane, sulfonate, hydroxyl and a combination of any of these.

11. The mixture according to claim 1, wherein the transparent polymer (130) is a branched polymer.

12. The mixture according to claim 1, wherein the IIB atom of the periodic table is Zn atom.

13. The mixture according to claim 1, wherein the semiconductor nanocrystal (110) contains a core and at least one shell, and the outermost shell contains Zn atom.

14. (canceled)

15. Method for preparing of the mixture according to claim 1, wherein the method comprises the step (A):
(A) mixing the semiconductor nanocrystal containing at least one IIB atom of the periodic table on the surface of the semiconductor nanocrystal, a ligand represented by following formula (I), a transparent polymer attached onto the ligand, and the transparent matrix material
*—X—Y—Z (I)
wherein the formula, X is selected from the group consisting of —X^{a}—, —X^{a}—X^{b}, —C(═X^{a})—X^{b}—, —NC(═X^{a})—X^{b}—, —X^{a}O₃—, —X^{a}—X^{b}O₃—, —PO₂H—, and PO₃H—, PO₄H—, with X^{a} and X^{b} being independently of each other S or Se, and X is attached onto the surface of the semiconductor nanocrystal (110); Y is selected from the group consisting of an alkylene chain having 1 to 25 carbon atoms, an alkoxylene chain having 1 to 25 carbon atoms, aryl group having 3 to 25 carbon atoms; Z is a polar group, anionic group or a cationic group.

16. An optical medium (100) comprising the mixture according to claim 1.

17. (canceled)

18. Method for preparing of the optical medium (100), wherein the method comprises the step (x):
(x) providing the mixture according to claim 1, onto a substrate.

19. An optical device comprising the optical medium according to claim 16.
